(19) United States
(12) Patent Application Publication
(10) Pub. No.: US 2025/0107381 A1
(43) Pub. Date: Mar. 27, 2025

(54) PIXEL ARRANGEMENT STRUCTURE AND ORGANIC LIGHT-EMITTING DIODE DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jinchang HUANG, Wuhan, Hubei (CN); Ming ZHANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/852,892

(22) PCT Filed: Jun. 29, 2023
(86) PCT No.: PCT/CN2023/104285

§ 371 Date: Sep. 30, 2024

(30) Foreign Application Priority Data
Dec. 20, 2022 (CN) 202211641149.9

(51) Int. Cl. H10K 59/35

(52) U.S. Cl. CPC H10K 59/352; H10K 59/353

(57) ABSTRACT

This application provides a pixel arrangement structure and an OLED display panel, which includes multiple pixel units, with at least one of the pixel units including: a blue pixel with a width B1 in a first direction and a length B2 in a second direction, B2 being greater than B1; a green pixel with a maximum dimension G1 in the first direction and a maximum dimension G2 in the second direction, G1/G2≤1; and a red pixel arranged side by side with the green pixel in the second direction; where, 1<(G1/G2)/(B1/B2)≤4.

### TECHNICAL FIELD

This application relates to display technology, particularly to a pixel arrangement structure and an organic light-emitting diode display panel.

### BACKGROUND

Organic light-emitting diode (OLED) display panels are known for their self-luminous, ultra-thin, wide viewing angle, fast response speed, low power consumption, and flexibility in display applications. However, traditional OLED display panels suffer from short lifespan and color bias issues.

Therefore, it is necessary to propose a technical solution to address the color bias issue of traditional OLED display panels while enhancing their lifespan.

### Technical Problem

The purpose of this application is to provide a pixel arrangement structure and an OLED display panel that address a color bias issue of the OLED display panel while enhancing the lifespan of the OLED display panel.

### Technical Solution

In a first aspect, this application provides a pixel arrangement structure a plurality of pixel units, wherein one or more of the plurality of pixel units each comprise:

a blue pixel with a width B1 in a first direction and a length B2 in a second direction, B2 being greater than B1, the first direction intersecting the second direction;

a green pixel with a maximum dimension G1 in the first direction and a maximum dimension G2 in the second direction, G1/G2≤1, the blue pixel being located on one side of the green pixel in the first direction; and

a red pixel arranged side by side with the green pixel in the second direction;

where, 1<(G1/G2)/(B1/B2)≤4.

In some embodiments of the pixel arrangement structure, 1.2≤(G1/G2)/(B1/B2)≤2.

In some embodiments of the pixel arrangement structure, 0.2≤B1/B2≤0.7.

In some embodiments of the pixel arrangement structure, 0.8≤G1/G2≤1.

In some embodiments of the pixel arrangement structure, the pixel units are arranged in the first and second directions, the first direction being perpendicular to the second direction;

all the blue pixels of two of the pixel units adjacent in the second direction are located on a same line, and all the red pixels and all the green pixels in the two pixel units adjacent in the second direction are on a same line and alternate with each other;

lines on which all the red pixels and all the green pixels of two of the pixel units adjacent in the first direction are located alternate with lines on which all the blue pixels of the two pixel units adjacent in the first direction are located.

In some embodiments of the pixel arrangement structure, a shape of the blue pixel is selected from at least one of oblong-rectangle, quasi-oblong-rectangle, ellipse, and dumbbell shapes, and shapes of the green pixel and the red pixel are each selected from at least one of rectangle, quasi-rectangle, ellipse, and dumbbell shapes.

In some embodiments of the pixel arrangement structure, the first direction is perpendicular to the second direction, wherein: the blue pixel is oblong-rectangular with its longer sides parallel to the second direction, and the green pixel is rectangular with one pair of sides parallel to the second direction; or the blue pixel is elliptical with its minor axis parallel to the first direction and its major axis parallel to the second direction, and the green pixel is rectangular with one pair of sides parallel to the second direction.

In some embodiments of the pixel arrangement structure, a maximum dimension of the red pixel in the first direction is R1, where 0.8≤G1/R1≤1.2, G1/B1>1, and R1/B1>1.

In some embodiments of the pixel arrangement structure, a maximum dimension of the red pixel in the second direction is R2, where R1/R2>1.

In some embodiments of the pixel arrangement structure, a light-emitting area of the blue pixel is greater than light-emitting areas of the green and red pixels.

In a second aspect, this application also provides an OLED display panel including the aforementioned pixel arrangement structure.

### Beneficial Effects

The blue pixel has a width B1 in the first direction and a length B2 in the second direction, with B2 greater than B1, and the green pixel has a maximum dimension G1 in the first direction and a maximum dimension G2 in the second direction, where G1/G2≤1. This is beneficial for the shapes of the green and blue pixels to be similar. Moreover, 1<(G1/G2)/(B1/B2)≤4, which ensures that when the dimensions of the pixel unit in the first direction and the second direction are fixed, the ratio of the maximum dimensions of the green pixel in the first direction and the second direction is greater than the ratio of the width B1 of the blue pixel in the first direction to its length B2 in the second direction, and the relatively small ratio between the two is beneficial for improving the color bias issue caused by the significant difference in dimension ratios of the blue and green pixels, which pixels tend to have similar shapes, in the first and second directions. At the same time, it is beneficial for the green pixel to have a larger maximum dimension in the first direction to increase its aperture ratio, and for the blue pixel to have a larger dimension in the second direction to increase its aperture ratio. This, in turn, helps to increase the combined aperture ratio of the green and blue pixels, thereby enhancing the lifespan of the pixel unit and balancing the lifespan and color bias issues of the OLED display panel.

### BRIEF DESCRIPTION OF THE DRAWINGS

FIG. 1 is a cross-sectional view of an embodiment of the OLED display panel according to this application.

FIG. 2 is a plan view of the pixel arrangement structure in embodiments of this application.

FIG. 3 is a plan view showing the pixel unit and the shading structure of the OLED display panel in embodiments of this application.

FIG. 4 is another second plan view showing the pixel unit and the shading structure of the OLED display panel in embodiments of this application.

FIG. 5 is yet another plan view of the pixel unit and the shading structure of the OLED display panel in embodiments of this application.

FIG. 6(A) is a side view in the first direction when the width B1 of the blue pixel is less than the maximum dimension of the green and red pixels in the first direction, and FIG. 6(B) is a side view in the second direction when the length B2 of the blue pixel is greater than the maximum dimension of the green and red pixels in the second direction.

### DETAILED DESCRIPTION

The following description, in conjunction with the figures of the embodiments of this application, provides a clear and complete description of the technical solutions in the embodiments of this application. It is evident that the described embodiments are only part of the embodiments of this application and not all of them. All other embodiments obtained by those skilled in the art without creative labor based on the embodiments in this application fall within the scope of protection of this application.

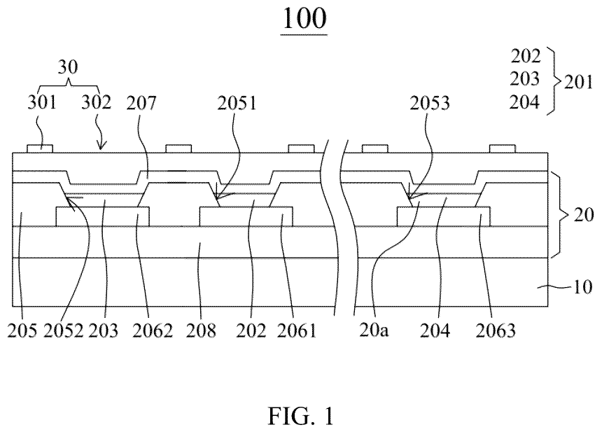

Refer to FIG. 1, which is the cross-sectional view of an embodiment of the OLED display panel of the application. The OLED display panel 100 includes the substrate 10, the pixel layer 20, and the shading structure 30. The pixel layer 20 is disposed on the substrate 10, and the shading structure 30 is on a side of the pixel layer 20 away from the substrate 10.

In this embodiment, the shading structure 30 includes multiple grid-shaped shading bodies 301 and multiple openings 302. Each shading body 301 is a closed ring structure, and an opening 302 is located within one shading body 301. The shading bodies 301 have a certain thickness and width, serving to block light. The openings 302 allow light to pass through.

The shading structure 30 includes a metal mesh of touch electrodes and/or the black matrix.

Specifically, the OLED display panel 100 includes a touch layer located on a light-emitting side of the pixel layer 20. The touch layer includes touch electrodes in the display area, which are composed of the metal mesh, and the shading structure 30 includes the metal mesh of the touch electrodes.

It is understood that when the OLED display panel 100 includes the color filter layer, the color filter layer is located on a light-emitting side of the pixel layer 20 and includes the black matrix. In this case, the shading structure 30 also includes the black matrix.

In this embodiment, the pixel layer 20 includes the pixel arrangement structure 20a, the driving circuit layer 208, the pixel definition layer 205, an anode layer, and the common cathode 207.

The driving circuit layer 208 is disposed on the substrate 10 and includes multiple arrayed thin-film transistors.

The anode layer is disposed on the driving circuit layer 208 and includes the spaced first anode 2061, second anode 2062, and third anode 2063, which are respectively connected to the drains of multiple thin-film transistors of the driving circuit layer 208.

The pixel definition layer 205 is disposed on the anode layer and the driving circuit layer 208 and includes the first pixel opening 2051, second pixel opening 2052, and third pixel opening 2053. The spacing between any two of the first pixel opening 2051, the second pixel opening 2052, and the third pixel opening 2053 in the first and second directions is the same. The first pixel opening 2051 corresponds to the first anode 2061, the second pixel opening 2052 corresponds to the second anode 2062, and the third pixel opening 2053 corresponds to the third anode 2063.

The pixel unit 201 consists of the blue pixel 202, the green pixel 203, and the red pixel 204. The blue pixel 202 is an organic light-emitting layer that emits blue light, the green pixel 203 is an organic light-emitting layer that emits green light, and the red pixel 204 is an organic light-emitting layer that emits red light.

The blue pixel 202 is located in the first pixel opening 2051 and on the first anode 2061, corresponding to one of the openings 302 with one of the shading bodies 301 surrounding the blue pixel 202. The green pixel 203 is located in the second pixel opening 2052 and on the second anode 2062, corresponding to one of the openings 302 with one of the shading bodies 301 surrounding the green pixel 203. The red pixel 204 is located in the third pixel opening 2053 and on the third anode 2063, corresponding to one of the openings 302 with one of the shading bodies 301 surrounding the red pixel 204.

The common cathode 207 covers the blue pixel 202, green pixel 203, red pixel 204, and the pixel definition layer 205. An thin-film encapsulation layer is provided between the common cathode 207 and the shading structure 30.

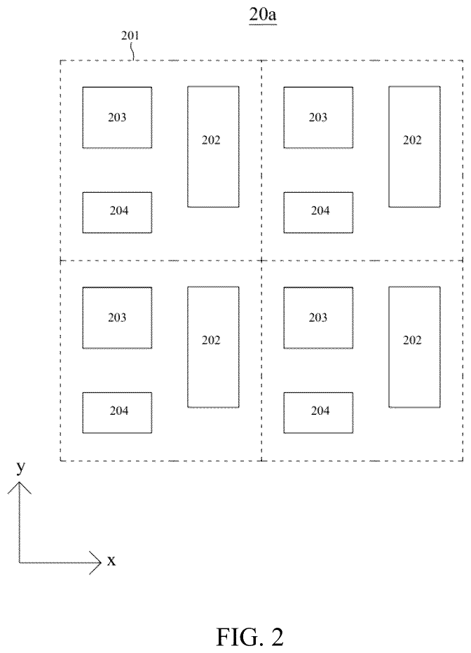

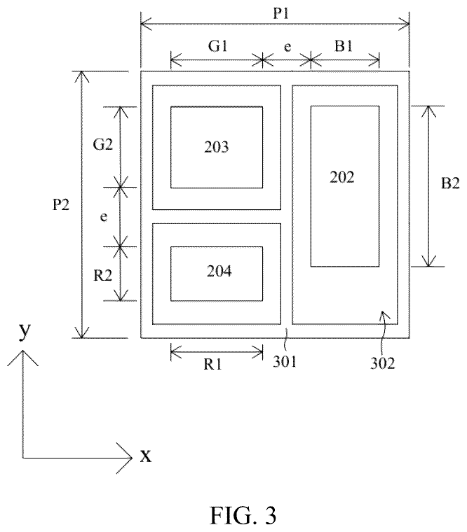

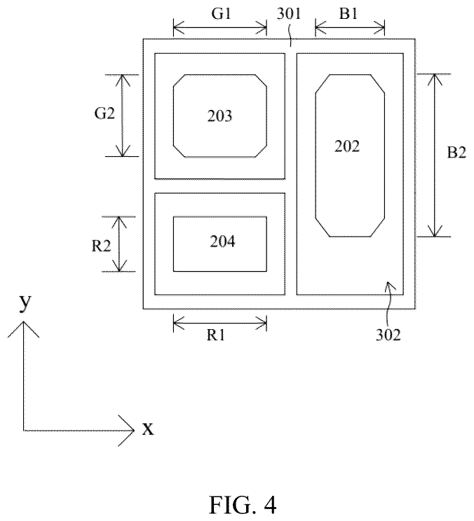

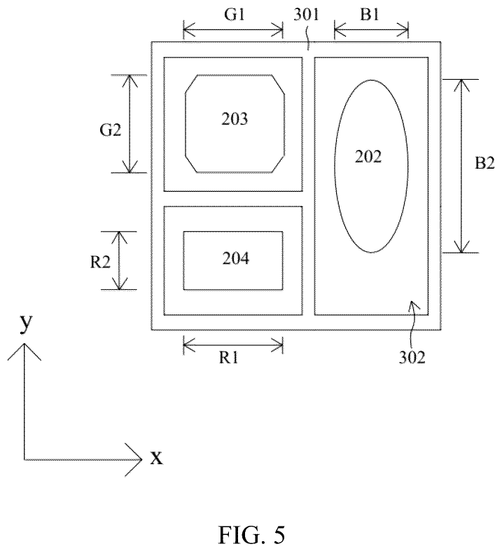

Refer to FIGS. 2, 3, 4, and 5. FIG. 2 is the plan view of the pixel arrangement structure in embodiments of this application. FIG. 3 is the plan view of the pixel unit and the shading structure of the OLED display panel in embodiments of this application. FIG. 4 is the another plan view of the pixel unit and the shading structure of the OLED display panel in embodiments of this application. FIG. 5 is the yet another plan view of the pixel unit and the shading structure of the OLED display panel in embodiments of this application.

In this embodiment, the pixel arrangement structure 20a includes multiple pixel units 201, which are arrayed in the first direction x and the second direction y, the first direction x intersecting the second direction y.

In this embodiment, the shape of each pixel unit 201 is square, but not limited to this, and the shape of each pixel unit 201 can also be oblong-rectangles or other shapes.

Specifically, the first direction x is perpendicular to the second direction y, but not limited to this, the angle between the first direction x and the second direction y can also be acute or obtuse.

In this embodiment, within the pixel unit 201, the green pixel 203 and the red pixel 204 are arranged side by side in the second direction y, and the blue pixel 202 is located on one side of the green pixel 203 and the red pixel 204 in the first direction x. In other words, the green pixel 203 and the red pixel 204 are in the same column, and the blue pixel 202 is in a separate column. The pixel unit 201 adopts the Real RGB pixel arrangement.

In this embodiment, in two adjacent pixel units 201 in the second direction y, the two blue pixels 202 are in the same column, and the red pixels 204 and the green pixels 203 are in the same row, alternating with each other. In adjacent pixel units 201 in the first direction x, the red pixel 204 and the green pixel 203 in the same column alternate with the column of blue pixel(s) 202.

In this embodiment, a light-emitting area of the blue pixel 202 is greater than that of the green pixel 203 and of the red pixel 204, increasing the light-emitting area of the blue pixel 202 and thereby enhancing the lifespan of the blue pixel 202.

Additionally, a light-emitting area of the green pixel 203 is greater than or equal to that of the red pixel 204, increasing the light-emitting area of the green pixel 203 and thereby enhancing the lifespan of the green pixel 203.

Specifically, the ratio of the light-emitting areas of the blue pixel 202, the green pixel 203, and the red pixel 204 is (1.8-2.0):1:(0.7-0.9).

It should be noted that the blue pixel 202, green pixel 203, and red pixel 204 are all composed of organic materials. The organic material that emits blue light has the shorter lifespan than the organic material that emits green light, and the organic material that emits green light has the shorter lifespan than the organic material that emits red light. Increasing the light-emitting areas of the blue pixel 202 and the green pixel 203 helps to enhance the lifespans of the blue pixel 202 and the green pixel 203.

In this embodiment, the sum of the light-emitting areas of the green pixel 203 and the red pixel 204 is greater than the light-emitting area of the blue pixel 202, to avoid the light-emitting area of the blue pixel 202 being too much larger than the light-emitting areas of the green pixel 203 and the red pixel 204, which would affect the display effect.

It should be noted that in this application, the light-emitting area of the pixel refers to an area of the light-emitting part of the pixel, which is the area of the organic light-emitting layer of the pixel.

As shown in FIGS. 3, 4, and 5, the blue pixel 202 has the width B1 in the first direction x and the length B2 in the second direction y, with B2 being greater than B1. In other words, the blue pixel 202 has a shape with length and width, presenting the shape that is narrow in the first direction x and long in the second direction y.

The width B1 of the blue pixel 202 is the maximum dimension of the blue pixel 202 in the first direction x, and the length B2 of the blue pixel 202 is the maximum dimension of the blue pixel 202 in the second direction y. The shape of the blue pixel 202 is selected from at least one of oblong-rectangles, quasi-oblong-rectangles, ellipses, and dumbbell shapes.

The green pixel 203 has the maximum dimension G1 in the first direction x and the maximum dimension G2 in the second direction y, where G1/G2≤1. The maximum dimension of the green pixel 203 in the first direction x is less than or equal to the maximum dimension in the second direction y, which is beneficial for the shape of the green pixel 203 to be similar to the shape of the blue pixel 202.

The red pixel 204 has the maximum dimension R1 in the first direction x and the maximum dimension R2 in the second direction y, where R1/R2>1. The maximum dimension of the red pixel 204 in the first direction x is greater than the maximum dimension in the second direction y.

In this embodiment, the shapes of the green pixel 203 and the red pixel 204 are each independently selected from at least one of rectangles, quasi-rectangles, ellipses, and dumbbell shapes.

It should be noted that rectangles and quasi-rectangles are similar, with quasi-rectangles including quasi-squares and quasi-oblong-rectangles. Quasi-squares are similar in shape to squares, including rounded corner squares and chamfered squares. Quasi-oblong-rectangles are similar in shape to oblong-rectangles, including rounded corner oblong-rectangles and chamfered oblong-rectangles. Chamfered oblong-rectangles are formed by removing one, two, three, or four right angles at the corners of the oblong-rectangle. Similarly, chamfered squares are formed by removing one, two, three, or four right angles at the corners of the square.

As shown in FIG. 3, when the blue pixel 202 is oblong-rectangular, the length direction of the oblong-rectangular blue pixel 202 is parallel to the second direction y, and the width direction of the oblong-rectangular blue pixel 202 is parallel to the first direction x. In other words, the length of the oblong-rectangular blue pixel 202 is B2, and the width is B1.

When the green pixel 203 is square, two adjacent sides of the square green pixel 203 are respectively parallel to the first direction x and the second direction y. The maximum dimension G1 of the green pixel 203 in the first direction x is equal to the maximum dimension G2 in the second direction y and is equal to a side length of the square green pixel 203.

When the red pixel 204 is oblong-rectangular, the length direction of the oblong-rectangular red pixel 204 is parallel to the first direction x, and the width direction of the oblong-rectangular red pixel 204 is parallel to the second direction y. In other words, the length of the oblong-rectangular red pixel 204 is R1, and the width is R2, that is, R1/R2>1.

As shown in FIG. 4, when the blue pixel 202 is the chamfered oblong-rectangle, the length direction of the chamfered oblong-rectangular blue pixel 202 is parallel to the second direction y, and the width direction of the chamfered oblong-rectangular blue pixel 202 is parallel to the first direction x. The maximum dimension of the chamfered oblong-rectangular blue pixel 202 in the first direction x is the width B1, and the maximum dimension in the second direction y is B2.

When the green pixel 203 is the chamfered square, the length and width of the chamfered square green pixel 203 are equal, and the length direction and width direction of the chamfered square green pixel 203 are respectively parallel to the first direction x and the second direction y. The length and width of the chamfered square green pixel 203 are G1 and G2, respectively, with G1=G2.

The shape of the red pixel 204 shown in FIG. 4 is the same as that shown in FIG. 3, and will not be repeated here.

As shown in FIG. 5, when the blue pixel 202 is elliptical, the minor axis of the elliptical blue pixel 202 is parallel to the first direction x, and the major axis of the elliptical blue pixel 202 is parallel to the second direction y. The dimension of the minor axis of the elliptical blue pixel 202 is the width B1 of the blue pixel 202, and the dimension of the major axis is the length B2 of the blue pixel 202.

The green pixel 203 is the chamfered oblong-rectangle, with the length direction of the chamfered oblong-rectangular green pixel 203 parallel to the second direction y, and the width direction parallel to the first direction x. The length of the chamfered oblong-rectangular green pixel 203 is G2, and the width is G1, with the length G2 being greater than the width G1.

The shape of the red pixel 204 shown in FIG. 5 is the same as that shown in FIG. 2, and will not be repeated here.

In this embodiment, G1/B1 >1 and R1/B1 >1, allowing the maximum dimensions of the green pixel 203 and the red pixel 204 in the first direction x to be greater than the width B1 of the blue pixel 202. This increases the light-emitting areas of the green pixel 203 and the red pixel 204 by utilizing the space in the first direction x, enhancing the lifespans of the green pixel 203 and the red pixel 204.

In this embodiment, B2/G2>1 and B2/R2>1, allowing the length B2 of the blue pixel 202 to be greater than the maximum dimensions of the green pixel 203 and the red pixel 204 in the second direction y. This increases the light-emitting area of the blue pixel 202 by utilizing the space in the second direction y, enhancing the lifespan of the blue pixel 202.

In this embodiment, the length B2 of the blue pixel 202 is greater than the sum of the maximum dimension G2 of the green pixel 203 and the maximum dimension R2 of the red pixel 204 in the second direction y. This ensures that the dimension of the blue pixel 202 in the second direction y is large enough, and when the light-emitting area of the blue pixel 202 is fixed, it is more beneficial to reduce the maximum dimension of the blue pixel 202 in the first direction x to have larger maximum dimensions of the green pixel 203 and the red pixel 204 in the first direction x, providing more space to increase the light-emitting areas of the green pixel 203 and the red pixel 204.

In this embodiment, as shown in FIG. 3, within the pixel unit 201, the spacing between the blue pixel 202 and the green pixel 203 in the first direction x, the spacing between the blue pixel 202 and the red pixel 204 in the first direction x, and the spacing between the green pixel 203 and the red pixel 204 in the second direction y are all equal and are e.

Additionally, in two adjacent pixel units 201 in the first direction x, the spacing between adjacent blue pixel 202 and green pixel 203, and the spacing between adjacent blue pixel 202 and red pixel 204 in the first direction x, are also both e. In the second direction y, the spacing between adjacent green pixel 203 and red pixel 204 from two adjacent pixel units 201 is also e.

The pixel unit 201 has the first dimension P1 in the first direction x and the second dimension P2 in the second direction y, with the first dimension P1 being equal to the second dimension P2. Here, the first dimension P1=B1+G1+2e, and the second dimension P2=G2+R2+2e. Both the first dimension P1 and the second dimension P2 are greater than or equal to 80 micrometers and less than or equal to 120 micrometers, for example, the first dimension P1 can be 80 micrometers, 100 micrometers, or 120 micrometers.

It should be noted that, as can be seen in conjunction with FIGS. 3, 4, and 5, when the dimensions of the pixel unit 201 in the first direction x and the second direction y are fixed, and since the blue pixel 202 is located in the separate column, it has the larger layout space in the second direction y. The width B1 of the blue pixel 202 in the first direction and the maximum dimension G1 of the green pixel 203 and red pixel 204 in the first direction x have the mutually restrictive relationship. The green pixel 203 and red pixel 204 are located in the same column, and their maximum dimensions in the second direction y also have the mutually restrictive relationship.

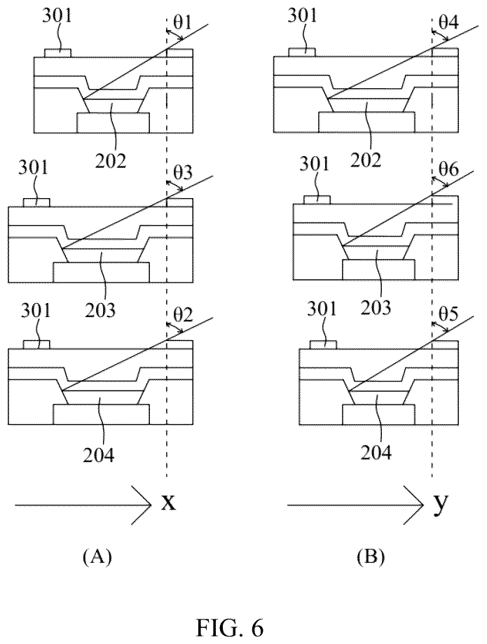

Furthermore, as can be seen in conjunction with FIG. 6(A), in the first direction x, when the width B1 of the blue pixel 202 is smaller than the maximum dimension of the green pixel 203 and red pixel 204 in the first direction x, the observation angle at which the blue light emitted by the blue pixel 202 is blocked by the shading body 301 is the first observation angle θ1, the observation angle at which the green light emitted by the green pixel 203 is blocked by the shading body 301 is the third observation angle θ3, the observation angle at which the red light emitted by the red pixel 204 is blocked by the shading body 301 is the second observation angle θ2, and θ1 is smaller than θ3 and θ2, causing the blue light emitted by the blue pixel 202 in the first direction x to be blocked first and to the greatest extent. A view from an observation angle between the first observation angle θ1 and the second observation angle θ2 has a yellowish tint due to the absence of blue light in the red and green lights mix.

In conjunction with FIG. 6(B), in the second direction y, when the width B1 of the blue pixel 202 is greater than the maximum dimension of the green pixel 203 and red pixel 204 in the second direction y, the observation angle at which the blue light emitted by the blue pixel 202 is blocked by the shading body 301 is the fourth observation angle θ4, the observation angle at which the red light emitted by the red pixel 204 is blocked by the shading body 301 is the fifth observation angle θ5, the observation angle at which the green light emitted by the green pixel 203 is blocked by the shading body 301 is the sixth observation angle θ6, and the fourth observation angle θ4 is greater than the sixth observation angle θ6 and the fifth observation angle θ5. In the second direction y, red and green lights are blocked first, while the blue light is blocked at the fourth observation angle θ4, which is the largest. This results in a bluish or cyanish tint in the second direction y.

In conjunction with FIGS. 2 to 5, it can be seen that when the dimensions of the pixel unit 201 in the first direction x and the second direction y are fixed, and the area of the blue pixel 202 and the dimensions of the green pixel 203 and the red pixel 204 in the second direction y remain constant, the larger the width B1 of the blue pixel 202, the smaller the dimensions of the green pixel 203 and the red pixel 204 in the first direction x. This leads to a smaller combined area of the green pixel 203 and red pixel 204, thereby reducing a combined aperture ratio of the pixel unit 201 and decreasing the lifespan of the pixel unit 201. At the same time, when the width B1 of the blue pixel 202 increases to be the same as the maximum dimension of the green pixel 203 and red pixel 204 in the first direction x, it helps to address the color bias in the first direction x of the pixel unit 201.

Conversely, when the dimensions of the pixel unit 201 in the first direction x and the second direction y are fixed, and the area of the blue pixel 202 and the dimensions of the green pixel 203 and the red pixel 204 in the second direction y remain constant, the smaller the width B1 of the blue pixel 202, the larger the dimensions of the green pixel 203 and the red pixel 204 in the first direction x. This results in a larger area for both the green pixel 203 and the red pixel 204, which is beneficial for increasing the combined aperture ratio of the green pixel 203, red pixel 204, and blue pixel 202. At the same time, the smaller the width B1 of the blue pixel 202, the larger the length B2 of the blue pixel 202, which reduces the ratio between the width B1 and the length B2 of the blue pixel 202. The maximum dimension of the green pixel 203 and red pixel 204 in the first direction x being larger than the width B1 of the blue pixel 202 can lead to the yellowish tint in the first direction x of the OLED display panel 100. The length B2 of the blue pixel 202 being larger than the maximum dimension of the green pixel 203 and red pixel 204 in the second direction y can lead to the bluish tint in the first direction x of the OLED display panel 100. That is different color biases in the first direction x and the second direction y of the OLED display panel 100 are resulted, and the OLED display panel 100 has poor color bias symmetry.

Therefore, when the dimensions of the pixel unit 201 in the first direction x and the second direction y are of fixed values, the variations of the width B1 of the blue pixel 202 in the first direction x and of the maximum dimension G1 of the green pixel 203 in the first direction x have opposite effects on the aperture ratio and color bias issues in the first direction x of the pixel unit 201. Moreover, the variation in the width B1 of the blue pixel 202 also affects the variation in the length B2 of the blue pixel 202 in the second direction y, thereby affecting the color bias in the second direction y of the pixel unit 201.

In this embodiment, when B2 is greater than B1 and G1/G2≤1, which is conducive to the shapes of the blue pixel 202 and the green pixel 203 tending to be the same, 1<(G1/G2)/(B1/B2)≤4, so that when the dimensions of the pixel unit 201 in the first direction x and the second direction y are fixed, the ratio of the maximum dimension of the green pixel 203 in the first direction x to its maximum dimension in the second direction y is greater than the ratio of the width B1 of the blue pixel 202 in the first direction to its length B2 in the second direction, and the relatively small ratio between the two is beneficial for improving the color bias issue caused by the significant difference in dimension ratios of the blue pixel 202 and green pixel 203 in the first and second directions. At the same time, it is beneficial for the maximum dimension G1 of the green pixel 203 and red pixel 204 in the first direction x to be larger, increasing the aperture ratio of the green pixel 203, and for the dimension of the blue pixel 202 in the second direction y to be larger, increasing the aperture ratio of the blue pixel 202. This, in turn, helps to increase the combined aperture ratio of the green pixel 203, blue pixel 202, and red pixel 204, enhancing the lifespan of the pixel unit 201 and balancing the lifespan and color bias issues of the OLED display panel 100.

Furthermore, 1.2≤(G1/G2)/(B1/B2)≤2, which may further increase the combined aperture ratio of the green pixel 203, red pixel 204, and blue pixel 202, and further enhance the lifespan of the OLED display panel 100 while also improving the color bias issue.

Moreover, 1.2≤(G1/G2)/(B1/B2)≤1.6, which may further enhance the combined aperture ratio of the green pixel 203, red pixel 204, and blue pixel 202, and to further improve the lifespan of the OLED display panel 100, while also significantly addressing the color bias issue.

For example, the value of (G1/G2)/(B1/B2) can be 1.1, 1.17, 1.2, 1.5, 1.7, 1.8, 1.9, 2, 2.1, 2.3, 2.5, 2.8, 3, 3.2, 3.5, or 3.8.

In this embodiment, 0.2≤B1/B2<1, which may further enhance the lifespan of the OLED display panel 100 while also improving the color bias issue. When B1/B2 is greater than or equal to 1, the width B1 of the blue pixel 202 in the first direction x is too large, resulting in the maximum dimension of the green pixel 203 and red pixel 204 in the first direction x being too small, which is not conducive to increasing the combined aperture ratio of the green pixel 203 and red pixel 204, and thus not conducive to enhancing the lifespan of the OLED display panel 100. When B1/B2 is less than 0.2, the length B2 of the blue pixel 202 in the second direction y is much greater than its width B1 in the first direction, and the length B2 of the blue pixel 202 is greater than the maximum dimension of the green pixel 203 and red pixel 204 in the second direction y. Meanwhile, the width B1 of the blue pixel 202 in the first direction x is much smaller than the maximum dimension of the green pixel 203 and red pixel 204 in the first direction, leading to the noticeable yellowish tint in the first direction x and the noticeable bluish tint in the second direction y of the OLED display panel 100.

Furthermore, 0.2≤B1/B2≤0.7, which may further enhance the lifespan of the OLED display panel 100 and address the color bias issue.

For example, B1/B2 can be 0.2, 0.25, 0.3, 0.4, 0.5, 0.6, 0.7, 0.8, or 0.9.

In this embodiment, 0.8≤G1/G2, which may further enhance the lifespan of the OLED display panel 100 and address the color bias issue. When G1/G2 is greater than 1, it causes the maximum dimension G1 of the green pixel 203 in the first direction x to be greater than the maximum dimension G2 in the second direction y. The lengths of the green pixel 203 and of the blue pixel 202 are disposed perpendicular to each other, leading to the severe greenish tint in the first direction x and the bluish tint in the second direction y of the pixel unit 201. When G1/G2 is less than 0.8, it results in the smaller maximum dimension G1 of the green pixel 203 in the first direction x, which is not conducive to increasing the aperture ratio of the green pixel 203, and thus not conducive to enhancing the aperture ratio of the pixel unit 201.

For example, G1/G2 can be 0.8, 0.83, 0.9, or 1.

In this embodiment, 0.8≤G1/R1≤1.2, allowing the dimensions of the red pixel 204 and the green pixel 203 in the first direction x to be equal, improving the color bias issue in the first direction x. Specifically, G1/R1=1.

Tables 1 and 2 below show the aperture ratios corresponding to different values of G1/G2, B1/B2, and (G1/G2)/(B1/B2) of the pixel unit 201, with first dimension P1 in the first direction x and second dimension P2 in the second direction y both being 100 micrometers, e being 22 micrometers, and (G1G2)/(B1B2)/(R1R2)=1:1.8:0.8, and show the corresponding Just Noticeable Color Differences (JNCDs) at 60-degree viewing angles in the length and width directions of the OLED display panel 100. Here, the first direction x is parallel to the length direction of the OLED display panel 100, and the second direction y is parallel to the width direction of the OLED display panel 100. The JNCD at a 60-degree viewing angles in the length and width directions is simply referred to as the 60-degree H-V symmetry, the JNCD at a 60-degree viewing angle in the length direction is simply referred to as the 60-degree H-direction color bias, and the JNCD at a 60-degree viewing angle in the width direction is simply referred to as the 60-degree V-direction color bias.

TABLE 1

| | G1 | 22 um | 25 um | 28 um | 30 um | 33 um | 35 um |
|---|---|---|---|---|---|---|---|
| G1/G2 = | B1/B2 | 1.11 | 0.71 | 0.46 | 0.35 | 0.22 | 0.17 |
| 0.83 | (G1/G2)/ | 0.75 | 1.17 | 1.8 | 2.4 | 3.71 | 4.88 |
| | (B1/B2) | | | | | | |
| | Aperture | 23% | 28% | 33% | 36% | 43% | 46% |
| | Ratio | | | | | | |
| | 60-degree | 1.5 | 0.6 | 1.6 | 1.8 | 2.0 | 2.5 |
| | H-V | | | | | | |
| | Symmetry | | | | | | |
| | 60-degree | 5.4 | 4.8 | 5.1 | 5.5 | 5.7 | 6.3 |
| | H-direction | | | | | | |
| | Color Bias | | | | | | |
| | 60-degree | 4.9 | 4.6 | 4.8 | 5.4 | 5.7 | 5.9 |
| | V-direction | | | | | | |
| | Color Bias | | | | | | |

From Table 1, it can be seen that when G1/G2=0.83, as G1 increases and B1/B2 decreases, (G1/G2)/(B1/B2) increases, the aperture ratio increases, and the JNCD of 60-degree H-V symmetry first decreases and then increases.

Additionally, when (G1/G2)/(B1/B2) is 0.75 and B1/B2 is 1.1, the aperture ratio of the pixel unit 201 is too small, which is not conducive to enhancing the lifespan of the OLED display panel 100. When (G1/G2)/(B1/B2) is 4.88 and B1/B2 is 0.17, the JNCD of 60-degree H-V symmetry is too large, indicating the significant issue with poor color bias symmetry in the OLED display panel 100. When (G1/G2)/(B1/B2) is greater than or equal to 1.17 and less than or equal to 3.71, and B1/B2 is greater than or equal to 0.22 and less than or equal to 0.71, the aperture ratio of the pixel unit 201 is greater than 28%, the JNCDs of 60-degree H direction and 60-degree V direction are less than or equal to 5.7, and the JNCD of 60-degree H-V symmetry is less than or equal to 2, which is beneficial for enhancing the lifespan of the OLED display panel 100 while improving its color bias issue.

TABLE 2

| | | | | | 60-degree | 60-degree | 60-degree |
|---|---|---|---|---|---|---|---|
| | | | | Aperture | H-V | H-direction | V-direction |
| G1 | G1/G2 | B1/B2 | (G1/G2)/(B1/B2) | Ratio | Symmetry | Color Bias | Color Bias |
| 25 um | 1.25 | 1.07 | 1.17 | 23% | 1.8 | 5.8 | 5.2 |
| | 1 | 0.85 | 1.17 | 25% | 0.7 | 4.9 | 4.7 |
| | 0.83 | 0.71 | 1.17 | 28% | 0.6 | 4.8 | 4.2 |
| | 0.67 | 0.57 | 1.17 | 31% | 1.5 | 5.1 | 4.8 |

From Table 2, it can be seen that when G1 is a constant value, as G2 increases, G1/G2 decreases, B1/B2 also decreases, (G1/G2)/(B1/B2) remains the constant value, the aperture ratio increases, and the JNCD of 60-degree H-V symmetry first decreases and then increases. The JNCD of the 60-degree H direction and 60-degree V direction color biases also decrease and then increase.

Additionally, when G1/G2 is 1.25, the aperture ratio of the pixel unit 201 is small, and the JNCD of 60-degree H-V symmetry is large, indicating the significant color bias issue in the OLED display panel 100. When G1/G2 is 0.67, the JNCD of 60-degree H-V symmetry is also large. When G1/G2 is greater than or equal to 0.83 and less than or equal to 1, the aperture ratio of the pixel unit 201 is greater than or equal to 25%, the JNCD of 60-degree H and 60-degree V are less than or equal to 4.9, and the JNCD of 60-degree H-V symmetry is less than or equal to 0.7, which is beneficial for enhancing the lifespan of the OLED display panel while improving its color bias issue.

The descriptions of the embodiments provided above are only for the purpose of helping to understand the technical solutions and core ideas of this application; those skilled in the art should understand that they can still modify the technical solutions recorded in the aforementioned embodiments, or equivalently substitute some of the technical features; and such modifications or substitutions do not deviate from the scope of the technical solutions of the embodiments of this application.

What is claimed is:

1. A pixel arrangement structure, comprising a plurality of pixel units, wherein one or more of the plurality of pixel units each comprise:
a blue pixel with a width B1 in a first direction and a length B2 in a second direction, B2 being greater than B1, the first direction intersecting the second direction;
a green pixel with a maximum dimension G1 in the first direction and a maximum dimension G2 in the second direction, G1/G2≤1, the blue pixel being located on one side of the green pixel in the first direction; and
a red pixel arranged side by side with the green pixel in the second direction;
where, 1<(G1/G2)/(B1/B2)≤4.

2. The pixel arrangement structure of claim 1, wherein 1.2≤(G1/G2)/(B1/B2)≤2.

3. The pixel arrangement structure of claim 1, wherein 0.2≤B1/B2<0.7.

4. The pixel arrangement structure of claim 1, wherein 0.8≤G1/G2≤1.

5. The pixel arrangement structure of claim 1, wherein the pixel units are arranged in the first and second directions, the first direction being perpendicular to the second direction;
all the blue pixels of two of the pixel units adjacent in the second direction are located on a same line, and all the red pixels and all the green pixels in the two pixel units adjacent in the second direction are on a same line and alternate with each other;
lines on which all the red pixels and all the green pixels of two of the pixel units adjacent in the first direction are located alternate with lines on which all the blue pixels of the two pixel units adjacent in the first direction are located.

6. The pixel arrangement structure of claim 1, wherein a shape of the blue pixel is selected from at least one of oblong-rectangle, quasi-oblong-rectangle, ellipse, and dumbbell shapes, and shapes of the green pixel and the red pixel are each selected from at least one of rectangle, quasi-rectangle, ellipse, and dumbbell shapes.

7. The pixel arrangement structure of claim 1, wherein the first direction is perpendicular to the second direction, wherein:
the blue pixel is oblong-rectangular with its longer sides parallel to the second direction, and the green pixel is rectangular with one pair of sides parallel to the second direction; or
the blue pixel is elliptical with its minor axis parallel to the first direction and its major axis parallel to the second direction, and the green pixel is rectangular with one pair of sides parallel to the second direction.

8. The pixel arrangement structure of claim 1, wherein a maximum dimension of the red pixel in the first direction is R1, 0.8≤G1/R1≤1.2, G1/B1>1, and R1/B1>1.

9. The pixel arrangement structure of claim 8, wherein a maximum dimension of the red pixel in the second direction is R2, and R1/R2>1.

10. The pixel arrangement structure of claim 1, wherein a light-emitting area of the blue pixel is greater than light-emitting areas of the green pixel and the red pixel.

11. An organic light-emitting diode display panel, comprising a pixel arrangement structure, the pixel arrangement structure comprising a plurality of pixel units, wherein one or more of the plurality of pixel units each comprise:
a blue pixel with a width B1 in a first direction and a length B2 in a second direction, B2 being greater than B1, the first direction intersecting the second direction;
a green pixel with a maximum dimension G1 in the first direction and a maximum dimension G2 in the second direction, G1/G231, the blue pixel being located on one side of the green pixel in the first direction; and
a red pixel arranged side by side with the green pixel in the second direction;
where, 1<(G1/G2)/(B1/B2)≤4.

12. The organic light-emitting diode display panel of claim 11, wherein 1.2≤(G1/G2)/(B1/B2)≤2.

13. The organic light-emitting diode display panel of claim 11, wherein 0.2≤B1/B2≤0.7.

14. The organic light-emitting diode display panel of claim 11, wherein 0.8≤G1/G2≤1.

15. The organic light-emitting diode display panel of claim 11, wherein the pixel units are arranged in the first and second directions, the first direction being perpendicular to the second direction;
all the blue pixels of two of the pixel units adjacent in the second direction are located on a same line, and all the red pixels and all the green pixels in the two pixel units adjacent in the second direction are on a same line and alternate with each other;
lines on which all the red pixels and all the green pixels of two of the pixel units adjacent in the first direction are located alternate with lines on which all the blue pixels of the two pixel units adjacent in the first direction are located.

16. The organic light-emitting diode display panel of claim 11, wherein a shape of the blue pixel is selected from at least one of oblong-rectangle, quasi-oblong-rectangle, ellipse, and dumbbell shapes, and shapes of the green pixel and the red pixel are each selected from at least one of rectangle, quasi-rectangle, ellipse, and dumbbell shapes.

17. The organic light-emitting diode display panel of claim 11, wherein the first direction is perpendicular to the second direction, wherein:
the blue pixel is oblong-rectangular with its longer sides parallel to the second direction, and the green pixel is rectangular with one pair of sides parallel to the second direction; or
the blue pixel is elliptical with its minor axis parallel to the first direction and its major axis parallel to the second direction, and the green pixel is rectangular with one pair of sides parallel to the second direction.

18. The organic light-emitting diode display panel of claim 11, wherein a maximum dimension of the red pixel in the first direction is R1, 0.8≤G1/R1≤1.2, G1/B1>1, and R1/B1>1.

19. The organic light-emitting diode display panel of claim 18, wherein a maximum dimension of the red pixel in the second direction is R2, and R1/R2>1.

20. The organic light-emitting diode display panel of claim 11, wherein a light-emitting area of the blue pixel is greater than light-emitting areas of the green pixel and the red pixel.
